(19) United States
(12) Patent Application Publication
(10) Pub. No.: US 2014/0004642 A1
(43) Pub. Date: Jan. 2, 2014

(54) MANUFACTURING METHOD FOR ORGANIC ELECTROLUMINESCENCE DEVICE

(71) Applicant: Canon Kabushiki Kaisha, Tokyo (JP)

(72) Inventors: Manabu Otsuka, Kawasaki-shi (JP); Tomoyuki Hiroki, Zama-shi (JP); Nobuhiko Sato, Yokohama-shi (JP)

(21) Appl. No.: 13/924,992

(22) Filed: Jun. 24, 2013

(30) Foreign Application Priority Data
Jun. 29, 2012 (JP) 2012-147949

(51) Int. Cl. H01L 51/52

(52) U.S. Cl. CPC H01L 51/52
USPC 438/46

(57) ABSTRACT

Provided is a manufacturing method for an organic electroluminescence device having high precision and high emission characteristics without degrading characteristics of an organic compound layer during lift-off, the manufacturing method including the steps of: forming a first organic compound layer; forming an intermediate layer; processing a first organic compound layer; forming a second organic compound layer; covering the second organic compound layer with an eluted constituent material for the intermediate layer by bringing the intermediate layer into contact with a solution for dissolving the intermediate layer; removing the intermediate layer; and forming a second electrode.

### BACKGROUND OF THE INVENTION

1. Field of the Invention

The present invention relates to a manufacturing method for an organic electroluminescence (EL) device.

2. Description of the Related Art

An organic EL device is a display device including multiple organic EL elements arranged in matrix on a substrate. For example, a multicolor display can be performed by arranging multiple organic EL elements respectively emitting light of different colors.

The organic EL element included in the organic EL device is an electronic element including an organic compound layer having a thickness of about tens of nm to hundreds of nm interposed between a pair of electrodes, and the organic compound layer forming the organic EL element includes at least an emission layer. Further, emission color of the organic EL element can be changed appropriately by selecting and changing a constituent material for the emission layer.

Meanwhile, a vacuum deposition method has been widely used for forming the organic compound layer. In the case of separately forming emission layers depending on the kinds of organic EL elements by the vacuum deposition method in a manufacturing process of a multicolor display organic EL device, predetermined emission layer materials are formed selectively in predetermined regions through use of a metal mask having openings corresponding to film formation regions. However, the vacuum deposition method using a metal mask can be said to be a method unsuitable for manufacturing a high precision display device due to low film formation accuracy caused by, for example, low alignment accuracy between the metal mask and a film formation substrate and thermal expansion of the metal mask.

In this context, Japanese Patent No. 4578026 discloses a method of selectively forming an organic compound layer with high accuracy through use of photolithography instead of a high precision metal mask. Specifically, the method involves providing a resist layer on a first emission layer formed on the entire surface of a substrate, patterning the resist layer by known photolithography, patterning (processing) the first emission layer through use of the resist layer, processing the first emission layer into a predetermined shape, forming a second emission layer separately from the first emission layer, dissolving the resist layer on the first emission layer in a solution for the resist layer, and removing (lifting off) the resist layer and layers provided on the resist layer.

### SUMMARY OF THE INVENTION

A manufacturing method of the present invention is a method for manufacturing an organic EL device including multiple organic EL elements each including a first electrode, an organic compound layer, and a second electrode laminated on a substrate in the stated order, the organic compound layer being patterned in a predetermined shape, the method including: a first organic compound layer forming step of forming a first organic compound layer on the substrate on which a plurality of the first electrodes are provided; an intermediate layer forming step of forming an intermediate layer on the first organic compound layer; a first organic compound layer processing step of selectively removing the intermediate layer and the first organic compound layer formed on some of the plurality of the first electrodes; a second organic compound layer forming step of forming a second organic compound layer on the first electrode provided in a region from which the first organic compound layer has been removed; a second organic compound layer covering step of covering the second organic compound layer with an eluted constituent material for the intermediate layer by bringing the intermediate layer into contact with a solution for dissolving the intermediate layer; an intermediate layer removing step of removing the intermediate layer and the eluted constituent material for the intermediate layer by dissolving the intermediate layer and the eluted constituent material for the intermediate layer through use of the solution; and a second electrode forming step of forming the second electrode on the first organic compound layer and the second organic compound layer.

Further features of the present invention will become apparent from the following description of exemplary embodiments with reference to the attached drawings.

### BRIEF DESCRIPTION OF THE DRAWINGS

FIGS. 1A and 1B are schematic sectional views illustrating examples of an organic EL device manufactured by a manufacturing method of the present invention.

FIGS. 2A, 2B, 2C, 2D, 2E, 2F, 2G, 2H, and 2I are schematic sectional views illustrating a manufacturing method for an organic EL device according to a first embodiment of the present invention.

FIGS. 3A, 3B, 3C, 3D, 3E, 3F, 3G, 3H, 3I, 3J, 3K, 3L, 3M, 3N, and 3O are schematic sectional views illustrating a manufacturing method for an organic EL device according to a second embodiment of the present invention.

FIGS. 4A, 4B, 4C, 4D, 4E, 4F, 4G, 4H, 4I, 4J, 4K, 4L, 4M, 4N, and 4O are schematic sectional views illustrating a manufacturing method for an organic EL device according to Example 1 of the present invention.

### DESCRIPTION OF THE EMBODIMENTS

In Japanese Patent No. 4578026, the following method is adopted. The method involves dissolving a resist layer and the like by bringing the resist layer and the like into contact with a stripping solution, and applying physical force to layers such as an emission layer formed on the eluted resist layer with an ultrasonic wave or the like. Japanese Patent No. 4578026 describes that, with this method, lift-off can be performed without damaging, in particular, an emission part of the first emission layer provided under the resist layer.

However, when lift-off is performed, a second emission layer formed on a base is exposed, and hence the characteristics of the second emission layer may be degraded in some cases due to the physical force to be applied to the second emission layer during lift-off. Further, when a layer which is not dissolved in the stripping solution for the resist layer is provided on the resist layer, a film chip of the layer which has been lifted off may damage the surface of the exposed second emission layer, which may result in emission defects in some cases.

The present invention has been made so as to solve the above-mentioned problems, and it is an object of the present invention to provide a method for manufacturing an organic EL device with high precision and high emission characteristics without degrading the characteristics of an organic compound layer during lift-off.

A manufacturing method of the present invention is a method for manufacturing an organic EL device including multiple organic EL elements each including a first electrode, an organic compound layer, and a second electrode laminated on a substrate in the stated order, the organic compound layer being patterned in a predetermined shape.

The method for manufacturing an organic EL device of the present invention includes the following steps (A) to (H):

(A) a first organic compound layer forming step of forming a first organic compound layer on multiple first electrodes;

(B) an intermediate layer forming step of forming an intermediate layer on the first organic compound layer;

(C) a first organic compound layer processing step of selectively removing the intermediate layer and the first organic compound layer formed on some of the multiple first electrodes;

(D) a second organic compound layer forming step of forming a second organic compound layer on the first electrode provided in a region from which the first organic compound layer has been removed;

(E) a second organic compound layer covering step of covering a surface of the second organic compound layer with an eluted constituent material for the intermediate layer by bringing the intermediate layer into contact with a solution for dissolving the intermediate layer;

(F) an intermediate layer removing step of removing the eluted constituent material for the intermediate layer through use of the solution; and

(G) a second electrode forming step of forming a second electrode on the first organic compound layer and the second organic compound layer.

In the present invention, it is preferred that the method for manufacturing an organic EL device further include a barrier layer forming step of forming a barrier layer on the intermediate layer between the intermediate layer forming step and the first organic compound layer processing step. Further, in the present invention, it is preferred that the method for manufacturing an organic EL device further include a barrier layer processing step of removing the barrier layer provided in a region from which the first organic compound layer is removed before the first organic compound layer processing step, in tandem with the barrier layer forming step.

According to the method for manufacturing an organic EL device of the present invention, in the lift-off step, that is, in the step (G), two kinds of organic compound layers (first organic compound layer, second organic compound layer) are both protected by the intermediate layer or an eluted constituent material for the intermediate layer formed of a material capable of being dissolved in the solution. Therefore, the two kinds of organic compound layers (first organic compound layer, second organic compound layer) can be prevented from being damaged by physical force to be applied thereto during lift-off or film chips which are not dissolved in the solution for the intermediate layer and are produced by the lift-off.

The embodiments of the present invention are specifically described below with reference to the drawings. Note that, regarding portions not shown particularly in the drawings or not described below specifically, well-known techniques or known techniques in the art can be applied. Note that the embodiments described below are merely examples of the embodiments of the present invention, and the present invention is not limited thereto.

(Organic EL Device)

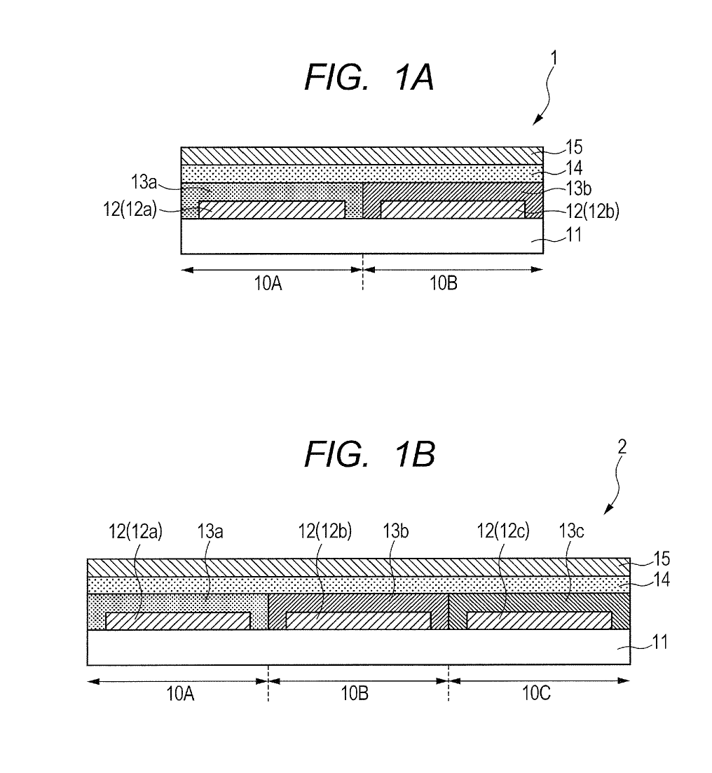

FIGS. 1A and 1B are schematic sectional views illustrating examples of an organic EL device to be manufactured by the manufacturing method of the present invention. Further, embodiments described below are manufacturing processes of any one of organic EL devices 1 and 2 of FIGS. 1A and 1B.

The organic EL device 1 of FIG. 1A includes two kinds of pixels: a first pixel 10A and a second pixel 10B. In the organic EL device 1 of FIG. 1A, the first pixel 10A includes a first organic EL element provided on a substrate 11, the first organic EL element including a first electrode 12 (12a), a first organic compound layer 13a, a common layer 14, and a second electrode 15 laminated in the stated order. In the organic EL device 1 of FIG. 1A, the second pixel 10B includes a second organic EL element provided on the substrate 11, the second organic EL element including a first electrode 12 (12b), a second organic compound layer 13b, the common layer 14, and the second electrode 15 laminated in the stated order. In the organic EL device 1 of FIG. 1A, the color of light output from each of the pixels (10A, 10B) varies depending on the kind of each of the organic compound layers (13a, 13b) forming the organic EL elements. More specifically, the color of light varies depending on the kind of each emission layer included in the organic compound layers (13a, 13b).

The organic EL device 2 of FIG. 1B includes three kinds of pixels: the first pixel 10A including a first organic EL element, the second pixel 10B including a second organic EL element, and a third pixel 10C including a third organic EL element. A group of the first pixel 10A, the second pixel 10B, and the third pixel 10C serve as a display unit for displaying an image. In the organic EL device 2 of FIG. 1B, the first pixel 10A includes the first organic EL element provided on the substrate 11, the first organic EL element including the first electrode 12 (12a), the first organic compound layer 13a, the common layer 14, and the second electrode 15 laminated in the stated order. In the organic EL device 2 of FIG. 1B, the second pixel 10B includes the second organic EL element provided on the substrate 11, the second organic EL element including the first electrode 12 (12b), the second organic compound layer 13b, the common layer 14, and the second electrode 15 laminated in the stated order. In the organic EL device 2 of FIG. 1B, the third pixel 10C includes the third organic EL element provided on the substrate 11, the third organic EL element including a first electrode 12 (12c), a third organic compound layer 13c, the common layer 14, and the second electrode 15 laminated in the stated order. In the organic EL device 2 of FIG. 1B, the color of light output from each of the pixels (10A, 10B, 10C) varies depending on the kind of each of the organic compound layers (13a, 13b, 13c) forming the organic EL elements. More specifically, the color of light varies depending on the kind of each emission layer included in the organic compound layers (13a, 13b, 13c).

Note that, in an actual organic EL device, multiple kinds of the pixels described above are arranged on the substrate 11 two-dimensionally in a multiple number, respectively having particular regularity.

### First Embodiment

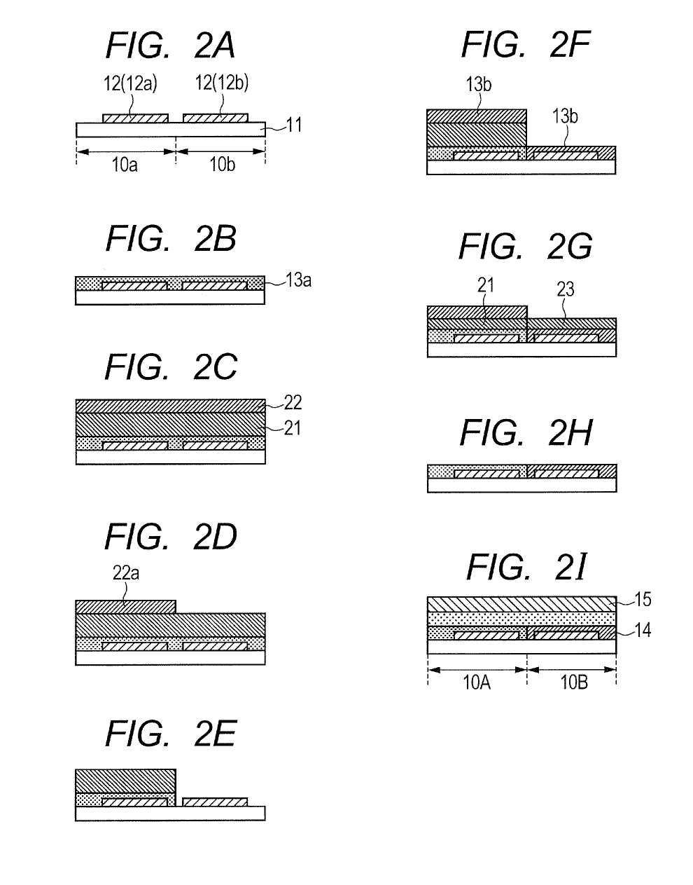

Next, a manufacturing process for the organic EL device 1 of FIG. 1A is described. FIGS. 2A to 21 are schematic sectional views illustrating a manufacturing method for an organic EL device according to a first embodiment of the present invention. A specific example of the manufacturing process for the organic EL device 1 of FIG. 1A is described hereinafter with reference to FIGS. 2A to 2I.

(1) Substrate

In FIGS. 2A to 2I, the substrate 11 to be used in the manufacturing process for the organic EL device 1 of FIG. 1A is not particularly limited as long as the substrate 11 enables the organic EL device 1 to be manufactured stably and to be driven. As the substrate 11, there may be given, for example, a substrate including an insulating or semiconductor supporting substrate such as glass or a Si wafer, on which a drive circuit for driving an organic EL device and a planarization layer for planarizing unevenness caused by the drive circuit are arranged. A part of the drive circuit is electrically connected to an external connecting terminal (not shown) via wiring.

(2) Step of Forming First Electrode (FIG. 2A)

When the organic EL device 1 of FIG. 1A is manufactured, first, the first electrodes 12 (12a, 12b) are formed on the substrate 11 on an element basis (FIG. 2A). Examples of a constituent material for the first electrode include a metal material such as Al or Ag, and a transparent electrode material such as indium tin oxide (ITO) or indium zinc oxide. Further, the first electrode 12 may be formed of a single layer or multiple layers. In the case where the first electrode 12 is formed of multiple layers, for example, a laminated electrode film can be used, in which a thin film made of the above-mentioned metal material and a thin film made of the above-mentioned transparent electrode material are laminated together.

The first electrode 12 is formed by forming a conductive layer on the entire surface of the substrate 11 by a known method such as a vacuum deposition method, a sputtering method, or a chemical vapor deposition (CVD) method, and patterning the conductive layer on an element basis through use of photolithography. As a result, the first electrodes (12a, 12b) are provided respectively in a multiple number in a region 10a in which the first organic EL element is to be provided and a region 10b in which the second organic EL element is to be provided (FIG. 2A). Note that a separation layer (not shown) covering ends of the first electrodes 12 may be further provided so as to separate the first electrodes 12 forming the organic EL elements on an element basis and to partition an emission region.

(3) Step of Forming First Organic Compound Layer (FIG. 2B)

Next, the first organic compound layer 13a is formed on the entire surface of the substrate 11 (FIG. 2B). The first organic compound layer 13a is a single layer or laminate formed of multiple layers including at least a first emission layer (not shown) for outputting light having a particular wavelength. In the case where the first organic compound layer 13a is a laminate formed of multiple layers, examples of layers forming the first organic compound layer 13a other than the first emission layer include a hole transport layer, a hole injection layer, an electron transport layer, and an electron injection layer. In the present invention, as a constituent material for the first organic compound layer 13a, a known low-molecular weight material or high-molecular weight material (polymer material) can be appropriately selected and used.

(4) Step of Processing First Organic Compound Layer (FIGS. 2C to 2E)

Next, the first organic compound layer 13a is processed by photolithography.

Specifically, first, an intermediate layer 21 and a resist layer 22 are formed on the first organic compound layer 13a in the stated order (FIG. 2C). The intermediate layer 21 is provided so as to protect the first organic compound layer 13a from damage in a later step.

As a constituent material for the intermediate layer 21, a material, which is dissolved in a solvent having low solubility with respect to a constituent material for the first organic compound layer 13a, is selected. The constituent material for the first organic compound layer 13a has low solubility in water, and hence water is suitably used as a solvent (solution) for dissolving the intermediate layer 21. In the case where water is selected as the solution, as the constituent material for the intermediate layer 21, a water-soluble inorganic material such as LiF or NaCl or a water-soluble polymer such as polyvinyl alcohol (PVA) or polyvinyl pyrrolidone (PVP) can be used.

Next, the resist layer 22 is formed on the intermediate layer 21 (FIG. 2C). The resist layer 22 serves as a mask layer 22a after being patterned into a desired shape by photolithography (FIG. 2D). In FIG. 2D, the resist layer 22 is patterned so that the mask layer 22a is selectively left in the region 10a in which the first EL element is to be provided.

When the resist layer 22 is formed, a material (resist material) is selected so that the etching rate of the resist layer 22 with respect to a developer to be used for developing the resist layer 22 becomes higher than that of the intermediate layer 21. Note that the developer for the resist layer 22 may have an effect of, for example, dissolving the first organic compound layer 13a and cause dissolution or alteration of the intermediate layer 21 in some cases. Considering this problem, it is preferred that a barrier layer (not shown) be provided so as to protect the intermediate layer 21 and the like from resist liquid before forming the resist layer 22 after forming the intermediate layer 21. As a constituent material for the barrier layer, an inorganic material such as silicon nitride or silicon oxide is preferably used. By providing the barrier layer, the possibility of the dissolution or alteration of the intermediate layer 21 and the first organic compound layer 13a during formation of the resist layer 22 can be suppressed. Further, choices of materials which can be used for forming the resist layer 22 to be formed on the intermediate layer 21 can be increased.

Note that a method of forming the mask layer 22a having a predetermined pattern on the intermediate layer 21 is not limited to photolithography, and an inkjet method, a printing method, or the like can be adopted.

After the mask layer 22a is formed, the intermediate layer 21 and the first organic compound layer 13a provided in a region where the mask layer 22a is not provided are removed through use of dry etching or wet etching. Thus, the intermediate layer 21 and the first organic compound layer 13a are patterned (FIG. 2E). As a result, the first electrode 12b provided in the region 10b in which the second organic EL element is to be provided is exposed. Note that the mask layer 22a may be removed simultaneously when the intermediate layer 21 and the first organic compound layer 13a are processed, as illustrated in FIG. 2E. Further, the mask layer 22a may be removed in a separate step after the intermediate layer 21 and the first organic compound layer 13a are processed.

(5) Step of Forming Second Organic Compound Layer (FIG. 2F)

Next, the second organic compound layer 13b is formed on the entire surface of the substrate 11 (FIG. 2F). The second organic compound layer 13b is a single layer or laminate formed of multiple layers including at least a second emission layer (not shown) for outputting light in a wavelength range different from that of the first emission layer (not shown). Further, in the case where the second organic compound layer 13b is a laminate formed of multiple layers, the second organic compound layer 13b may include a hole transport layer, a hole injection layer, an electron transport layer, an electron injection layer, and the like in addition to the second emission layer.

Further, similarly to the first organic compound layer 13a, a constituent material for the second organic compound layer 13b needs to be a material having low solubility in a solution for dissolving the intermediate layer 21. That is, the solution and the constituent material for the intermediate layer 21 are selected so that the etching rate of the intermediate layer 21 with respect to the solution becomes sufficiently higher than those of the first organic compound layer 13a and the second organic compound layer 13b with respect to the solution.

(6) Step of Covering Second Organic Compound Layer (FIG. 2G)

Next, before the layers formed on the first organic compound layer 13a are removed by lift-off, the surface of the second organic compound layer 13b is covered through use of the intermediate layer 21 remaining in the region 10a so as to protect the second organic compound layer 13b during lift-off (FIG. 2G). By covering the second organic compound layer 13b, the second organic compound layer 13b is not damaged by film chips of the mask layer 22a, the second organic compound layer 13b, the barrier layer, and the like which have been lifted off. Further, the characteristics of the organic compound layers (13a, 13b) can be prevented from being degraded by physical force applied to the organic compound layers (13a, 13b) during lift-off.

A method using the intermediate layer 21 involves dissolving the intermediate layer 21 by bringing a solution into contact with the intermediate layer 21 and eluting the constituent material for the intermediate layer 21 by taking advantage of the pattern of the intermediate layer 21 provided on the first organic compound layer 13a. In this method, the constituent material for the intermediate layer 21 mixed with the solution is spread from the surface of the first organic compound layer 13a to the surface of the second organic compound layer 13b to cover the surface of the second organic compound layer 13b.

Note that, if the substrate 11 is immersed in a bath containing a solution so as to bring the solution into contact with the intermediate layer 21, the constituent material for the intermediate layer 21 disperses in the bath without remaining on the surfaces of the organic compound layers (13a, 13b). Therefore, when this step is performed by immersing the substrate 11 in the bath filled with the solution, it is preferred that the substrate 11 be arranged upward and the solution be poured gently so as not to cause a flow of the solution. In addition, it is necessary to select the constituent material for the intermediate layer 21 so that the specific gravity of the constituent material in a solution state for the intermediate layer 21 is at least higher than that of the solution and the constituent material for the intermediate layer 21 sinks in the solution. When such a material is selected and the intermediate layer 21 is eluted with the treatment surface of the substrate 11 arranged upward, the eluted constituent material for the intermediate layer 21 can be uniformly spread onto the second organic compound layer 13b.

Besides the above-mentioned method, there is given a method involving supplying an appropriate amount of a solution to the surface of the substrate 11 with the treatment surface thereof held upward, instead of immersing the substrate 11 in the bath filled with the solution. This method is more preferred because it is not necessary to consider the specific gravity and the like of the intermediate layer 21 and the solution. Note that, when the solution is supplied continuously to the surface of the substrate 11 through use of a shower or the like, the constituent material for the intermediate layer 21 may be washed out of the substrate 11 without remaining on the surface of the second organic compound layer 13b in some cases. Therefore, it is necessary to check and consider the time required for covering the surface of the second organic compound layer 13b with a solution obtained when the intermediate layer 21 having come into contact with the solution is dissolved, the amount of the solution to be supplied, and the like. It is preferred to set a condition under which the thickness of an eluted constituent material 23 for the intermediate layer 21 covering the surface of the second organic compound layer 13b becomes maximum.

A method of covering the surface of the second organic compound layer 13b through use of the intermediate layer 21 is specifically described below.

First, the surface of the substrate 11 (surface on which the organic compound layers (13a, 13b) are provided) is directed upward, and a predetermined amount of a solution is supplied from the surface of the substrate 11 to be brought into contact with the intermediate layer 21. Thus, the intermediate layer 21 provided on the first organic compound layer 13a is dissolved. Then, the substrate 11 is allowed to stand still for a predetermined period of time. Thus, the constituent material for the intermediate layer 21 starts being dissolved and eluted from the intermediate layer 21 provided on the first organic compound layer 13a and spreads onto the surface of the second organic compound layer 13b. As a result, the second organic compound layer 13b is covered with the eluted constituent material 23 for the intermediate layer 21.

Alternatively, the substrate 11 may be rotated through use of a rotation mechanism such as a spin coater instead of allowing the substrate to stand still. With this rotation, the solution can be supplied to the substrate 11 efficiently, and the constituent material 23 for the intermediate layer 21 dissolved in the solution can be spread forcefully and efficiently with centrifugal force. This allows the eluted constituent material 23 for the intermediate layer 21 to be easily formed uniformly on the second organic compound layer 13b.

This step (step of covering the second organic compound layer) may be performed as a process continuing to a lift-off step to be performed subsequently.

(7) Lift-Off Step (FIG. 2H)

Next, the eluted constituent material 23 for the intermediate layer 21 is removed from the substrate 11, and the members such as the second organic compound layer 13b formed on the first organic compound layer 13a are removed by lift-off (peeling) (FIG. 2H).

As the solution for removing the eluted constituent material 23 for the intermediate layer 21, a solvent having low solubility with respect to the first organic compound layer 13a and the second organic compound layer 13b is used.

In particular, when water is used as the solution, the layers (first organic compound layer 13a, second organic compound layer 13b, barrier layer, etc.) other than the eluted intermediate layer 23 are not dissolved, and hence the eluted constituent material 23 for the intermediate layer 21 can be removed selectively.

When the lift-off step is performed by immersing the substrate 11 in the bath filled with the solution, it is necessary to apply force so as to peel the layers (second organic compound layer 13b, etc.) provided on the first organic compound layer 13a. As a specific lift-off method, there may be given a method involving creating a liquid stream on the substrate 11 and washing away the layers provided on the first organic compound layer 13a together with the eluted constituent material 23 for the intermediate layer 21 through use of the liquid stream. Further, existing methods using a two-fluid, an ultrasonic wave, megasonic washing, micro bubbling, a high-pressure spray, and the like, involving applying physical force to the solution, are used suitably, and in this case, the solution is supplied through a nozzle. Note that the present invention is not limited to these methods.

Further, the above-mentioned methods can be used after adjusting force to be applied to the solution to such a degree that at least the second organic compound layer 13b provided on the first organic compound layer 13a is removed, and the organic compound layers (13a, 13b) included in the respective organic EL elements do not peel from the substrate 11.

Further, in the case of performing lift-off by supplying the solution to the surface of the substrate 11 with the treatment surface thereof held upward, a method of supplying the solution supplied with physical force through use of a nozzle to (the surface of) the substrate 11 can be used. In the case of using this method, it is preferred that the nozzle for supplying the solution scan the substrate 11 relatively. As a method of allowing a nozzle to scan the substrate 11, there may be given, for example, a method involving moving a nozzle while allowing the substrate 11 to stand still, a method involving moving the substrate 11 with a nozzle fixed, and a method involving moving a nozzle while rotating the substrate 11, which can be selected as appropriate.

Further, in the case of performing the lift-off step using a nozzle, it is necessary to prevent the layers (second organic compound layer 13b, barrier layer, etc.), formed on the intermediate layer 21 and made of materials which are not dissolved in the solution, from re-adhering to the substrate 11. As a method of preventing the re-adhesion, there is given a method involving appropriately adjusting the shape, operation, height, angle, and the like of a nozzle, and there may also be given a method involving arranging multiple nozzles in some cases. Further, there may be given a method involving moving a nozzle so that the nozzle scans the substrate 11 while supplying a stripping solution onto the substrate 11 through use of another pipe separate from the nozzle so as to prevent the surface of the substrate 11 from being dried during the movement of the nozzle and the films which have been lifted off from re-adhering to the surface of the substrate 11. Further, in addition to the application of physical force, the solution to be used for lift-off may be heated as appropriate or CO₂ may be dissolved in or a surfactant may be added to the solution so as to prevent the re-adhesion caused by electrostatic force, to such a degree as not to influence element characteristics.

(8) Step of Forming Second Electrode, Etc.

Finally, the common layer 14 and the second electrode 15 are formed on the first organic compound layer 13a and the second organic compound layer 13b successively as layers shared by the respective organic EL elements. Thus, the organic EL device 1 including two kinds of organic EL elements is completed (FIG. 2I). Note that the formation of the common layer 14 may be omitted.

In the case where residues of the intermediate layer 21 and the like remain on the surfaces of the first organic compound layer 13a and the second organic compound layer 13b prior to the formation of the common layer 14 or the second electrode 15, the step of removing the residues is added. Specifically, the surface of each of the organic compound layers (13a, 13b) is etched by about several nm together with the materials for the intermediate layer 21 and the like through use of diluted alcohol or the like.

In the case of forming the common layer 14 on the first organic compound layer 13a and the second organic compound layer 13b, no particular limitation is imposed on the layer configuration of the common layer 14. For example, in the case where the first electrode 12 is an anode, examples of the common layer 14 include an electron transport layer and an electron injection layer. Further, in the case where the first electrode 12 is a cathode, examples of the common layer 14 include a hole transport layer and a hole injection layer. Further, the common layer 14 may be formed of a single layer or multiple layers.

As a constituent material for the second electrode 15, there are given known electrode materials such as a metal material (Al, Ag, etc.) and a transparent electrode material (indium tin oxide (ITO), indium zinc oxide, etc.). Further, the second electrode 15 may be formed of a single layer or multiple layers. In the case where the second electrode 15 is formed of multiple electrodes, the second electrode 15 may be formed of, for example, a laminated electrode film in which a layer made of the above-mentioned metal material and a layer made of the above-mentioned transparent conductive material are laminated.

Note that, in order to output light generated from each of the organic compound layers (13a, 13b) outside, at least any one of the first electrode 12 and the second electrode 15 is formed of a transparent or semi-transparent electrode layer. The “transparent layer” as used herein refers to a layer having a transmittance of 80% or more with respect to visible light, and the “semi-transparent layer” as used herein refers to a layer having a transmittance of 20% or more and less than 80% with respect to visible light. In order to prevent moisture from entering the organic EL element from outside after the second electrode 15 is formed, it is preferred to provide a known sealing member (not shown).

An exemplary embodiment of the manufacturing method of the present invention is described above. In the manufacturing method of the present invention, the surface of the second organic compound layer 13b is covered with the eluted constituent material 23 for the intermediate layer 21 when the unnecessary layers formed on the first organic compound layer 13a are lifted off. Therefore, members to be lifted off such as the second organic compound layer 13b peeled from the first organic compound layer 13a can be prevented from coming into direct contact with (the surface of) the second organic compound layer 13b to damage the surface or the occurrence of damage can be prevented from causing leakage or short-circuit. Further, the eluted constituent material 23 for the intermediate layer 21 covering (the surface of) the second organic compound layer 13b protects the second organic compound layer 13b from physical force which may be applied to the surface of the substrate 11 to degrade the characteristics of the organic EL element during the lift-off step.

### Second Embodiment

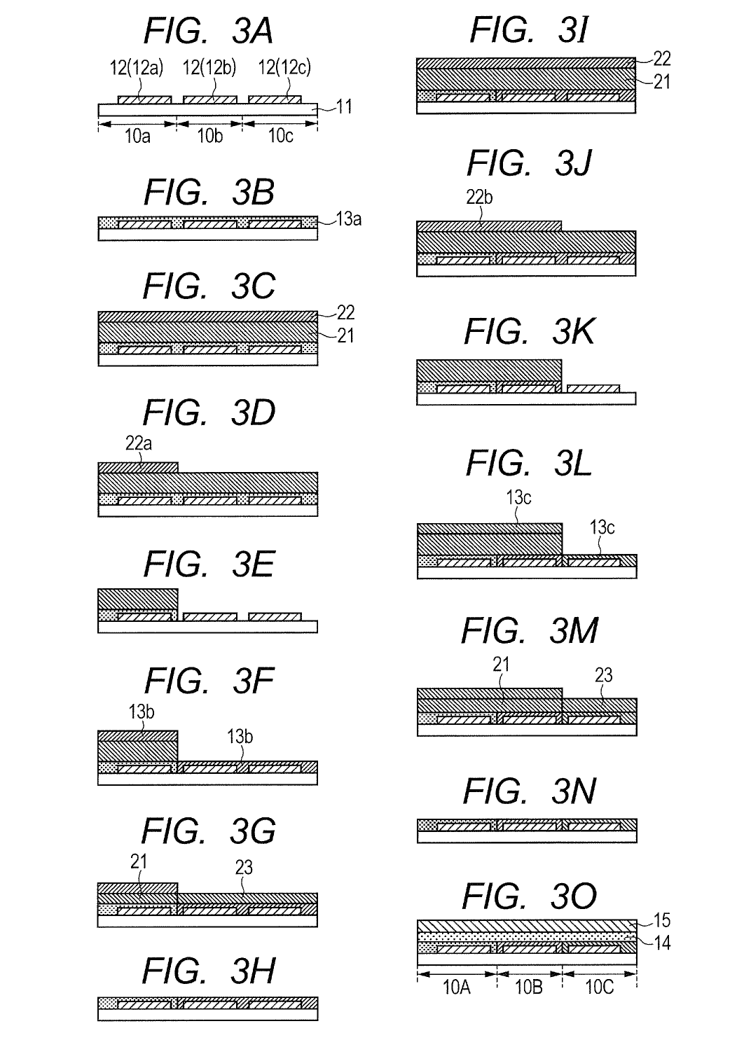

FIGS. 3A to 3O are sectional views illustrating a method for manufacturing an organic EL device according to a second embodiment of the present invention. The second embodiment is different from the first embodiment in that three kinds of pixels are formed. A specific example of a manufacturing process for the organic EL device 2 of FIG. 1B is described below with reference to FIGS. 3A to 3O.

(Step of Forming First Electrode to Step of Processing First Organic Compound Layer) (FIGS. 3A to 3E)

In the case of manufacturing the organic EL device 2 illustrated in FIG. 1B including three kinds of organic EL elements, the step of forming the first electrodes 12 (12a, 12b, 12c) to the step of processing the first organic compound layer 13a can be performed by the same method as that of the first embodiment. That is, the steps of FIGS. 3A to 3E including the step of forming the first organic compound layer 13a and the step of forming the intermediate layer 21 and the resist layer 22 can be performed by the same process as that illustrated in FIGS. 2A to 2E.

(Step of Forming Second Organic Compound Layer to Lift-Off Step) (FIGS. 3F to 3H)

Next, the second organic compound layer 13b is formed. In this case, at least in the region 10b in which the second organic EL element is to be provided and a region 10c in which the third organic EL element is to be provided, the second organic compound layer 13b is formed on the first electrodes (12b, 12c) (FIG. 3F). Then, an eluted constituent material for the intermediate layer 23 is formed through use of the intermediate layer 21 formed on the first organic compound layer 13a (FIG. 3G). The second organic compound layer 13b formed on the intermediate layer 21 is removed by lift-off (FIG. 3H). Note that, in the process described above, regarding the step of forming the eluted constituent material for the intermediate layer 23 to the lift-off step, the method described in the first embodiment may be adopted.

(Step of Processing Second Organic Compound Layer) (FIGS. 3I to 3K)

After the first lift-off step is performed, the second organic compound layer 13b is processed by photolithography (FIGS. 3I to 3K). In this step, specifically, the second organic compound layer 13b provided in regions other than the region 10b in which the second organic EL element is to be provided is removed. Note that the process illustrated in FIGS. 3I to 3K is a process for processing the second organic compound layer 13b through use of a laminate including the intermediate layer 21 and the resist layer 22, and a specific method therefor is the same as that described in the first embodiment. Note that a constituent material for the intermediate layer 21 to be used for processing the second organic compound layer 13b may be the same as or different from a material to be used as a constituent material for the intermediate layer 21 for processing the first organic compound layer 13a.

(Step of Forming Third Organic Compound Layer to Lift-Off Step) (FIGS. 3L to 3N)

Next, the third organic compound layer 13c is formed. In this case, the third organic compound layer 13b is formed at least in the region 10c in which the third organic EL element is to be provided (FIG. 3L). Then, the eluted constituent material for the intermediate layer 23 is formed through use of the intermediate layer 21 formed on the first organic compound layer 13a and the second organic compound layer 13b (FIG. 3M). Then, the third organic compound layer 13c formed on the intermediate layer is removed by lift-off (FIG. 3N). Note that, in the process described above, regarding the step of forming the eluted constituent material for the intermediate layer 23 to the lift-off step, the method described in the first embodiment may be adopted.

(Step of Forming Common Layer) (FIG. 3O)

Finally, the common layer 14 and the second electrode 15 which are shared by the respective organic EL elements are formed in the stated order. Thus, the organic EL device 2 illustrated in FIG. 1B is completed. Note that, as specific methods of forming the common layer 14 and the second electrode 15, the same methods as those of the first embodiment can be used.

The present invention is hereinafter described specifically by way of examples.

### Example 1

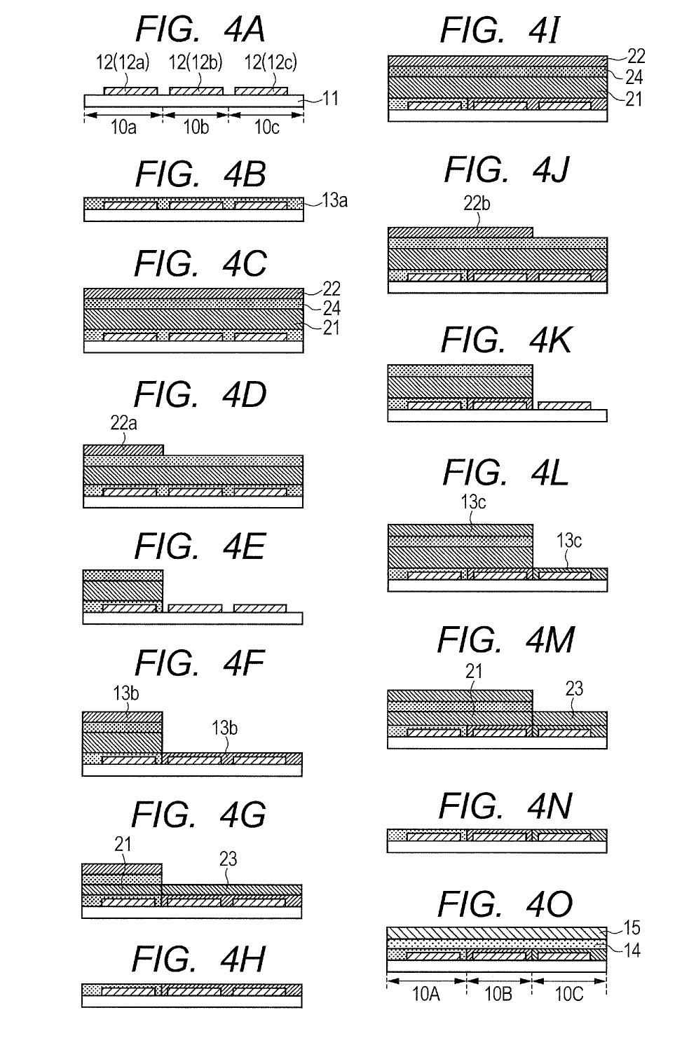

The organic EL device illustrated in FIG. 1B was manufactured in accordance with a manufacturing process illustrated in FIGS. 4A to 4O. The substrate 11 used in this example includes a glass substrate (not shown) which is a base, a circuit (not shown) provided on the base, for driving the respective organic EL elements individually, and an insulating layer for covering the circuit. Further, although not shown in FIG. 1B, the respective first electrodes (12a, 12b, 12c) are electrically connected to the circuit through contact holes (not shown) provided in the insulating layer.

(1) Step of Forming First Electrode

First, an AlNd film was formed to provide a reflective electrode layer on the entire surface of the substrate 11 by a sputtering method. In this case, the thickness of the reflective electrode layer was set to 100 nm. Then, an ITO film was formed on the reflective electrode layer to provide a transparent electrode layer by the sputtering method. In this case, the thickness of the transparent electrode layer was set to 10 nm. Then, the laminated electrode film including the reflective electrode layer and the transparent electrode layer was patterned by known photolithography. Thus, the first electrodes (12a, 12b, 12c) each including the reflective electrode layer and the transparent electrode layer were formed so that the first electrodes (12a, 12b, 12c) were provided in the regions (10a, 10b, 10c) in which respective organic EL elements were to be provided, respectively (FIG. 4A).

(2) Step of Forming First Organic Compound Layer

Next, the first organic compound layer 13a formed of multiple layers including a first emission layer emitting blue light was formed on the first electrodes (12a, 12b, 12c) and the substrate 11 by continuous film formation using a vacuum deposition method.

First, a hole transport layer was formed on the first electrodes (12a, 12b, 12c) and the substrate 11. In this case, the thickness of the hole transport layer was set to 120 nm. Then, a first emission layer containing a blue light-emitting material was formed on the hole transport layer. In this case, the thickness of the first emission layer was set to 30 nm. Then, a hole block layer was formed on the first emission layer. In this case, the thickness of the hole block layer was set to 10 nm. Thus, the first organic compound layer 13a was formed (FIG. 4B).

(3) Step of Forming Intermediate Layer

Next, polyvinyl pyrrolidone (PVP) as a water-soluble polymer material and water were mixed to prepare a PVP aqueous solution. Then, the prepared PVP aqueous solution was applied onto the first organic compound layer 13a to form a film by a spin coating method. The film was dried to form the intermediate layer 21. In this case, the thickness of the intermediate layer 21 was 2 μm.

(4) Step of Forming Barrier Layer

Next, a silicon nitride film was formed to provide a barrier layer 24 on the intermediate layer 21. In this case, the thickness of the barrier layer 24 was set to 2 μm.

(5) Step of Forming Resist Layer

Next, a commercially available photoresist material (“AZ1500” (trade name) manufactured by AZ Electronic Materials) was formed into a film on the barrier layer 24 by a spin coating method, and thereafter, a solvent in the photoresist material was evaporated to form the resist layer 22 (FIG. 4C). In this case, the thickness of the resist layer 22 was 1 μm.

(6) Step of Processing First Organic Compound Layer

Next, the substrate 11 with the layers including the resist layer 22 formed thereon was set in an exposure device, and was exposed to light for 40 seconds through a photomask having openings in regions other than the region 10a in which a first organic EL element was to be provided. After the exposure to light, the resist layer was developed for 1 minute through use of a developer (obtained by diluting “312 MIF” (trade name) manufactured by AZ Electronic Materials with water to a concentration of 50%) for a resist layer. The resist layer 22 formed in the region 10b in which a second organic EL element was to be provided and the region 10c in which a third organic EL element was to be provided were removed by the developing treatment (FIG. 4D).

Next, dry etching was performed for 17 minutes through use of the remaining resist layer 22a as a mask under the following conditions. Thus, the barrier layer 24 formed in the region 10b in which the second organic EL element was to be provided and the region 10c in which the third organic EL element was to be provided was removed.

### Reaction gas: CF₄

Flow rate of reaction gas: 30 sccm

### Pressure: 10 Pa

### Output: 150 W

Next, dry etching was performed for 5 minutes under the following conditions. Thus, the intermediate layer 21 formed in the region 10b in which the second organic EL element was to be provided and the region 10c in which the third organic EL element was to be provided was removed.

### Reaction gas: O₂

Flow rate of reaction gas: 20 sccm

### Pressure: 10 Pa

### Output: 150 W

Next, dry etching was performed under the same conditions as those for removing the intermediate layer 21 described above. Thus, the first organic compound layer 13a formed in the region 10b in which the second organic EL element was to be provided and the region 10c in which the third organic EL element was to be provided was removed (FIG. 4E).

Through the above-mentioned steps, the first organic compound layer 13a was formed selectively in the region 10a in which the first organic EL element was to be provided. Note that, when dry etching performed for processing the first organic compound layer 13a was completed, the resist layer 22a formed on the barrier layer 24 disappeared in the region 10a in which the first organic EL element was to be provided, as illustrated in FIG. 4E.

(7) Step of Forming Second Organic Compound Layer

Next, the second organic compound layer 13b formed of multiple layers including a second emission layer emitting red light was formed at least on the first electrodes (12b, 12c) by continuous film formation using a vacuum deposition method.

First, a hole transport layer was formed at least on the first electrodes (12b, 12c). In this case, the thickness of the hole transport layer was set to 200 nm. Then, a second emission layer containing a red light-emitting material was formed on the hole transport layer. In this case, the thickness of the second emission layer was set to 30 nm. Then, a hole block layer was formed on the second emission layer. In this case, the thickness of the hole block layer was set to 10 nm. Thus, the second organic compound layer 13b was formed (FIG. 4F).

(8) Step of Covering Second Organic Compound Layer

Next, the substrate 11 with the layers including the second organic compound layer 13b formed thereon was put in a device including a rotation mechanism and a mechanism formed of a supply pipe for a solution and a two-fluid nozzle, and then, the substrate 11 was adsorbed to a stage of the rotation mechanism with the treatment surface of the substrate 11 arranged upward. Then, while the substrate 11 was rotated at a rotation number of 500 rpm through use of the rotation mechanism, water which was a solution for the intermediate layer 21 was supplied onto the substrate 11 at a flow rate of 1 L/min for 5 seconds through use of a supply nozzle, and then the supply was suspended temporarily. Thus, the second organic compound layer 13b was covered with the eluted constituent material 23 for the intermediate layer 21 (FIG. 4G). In this case, the thickness of the constituent material 23 covering the second organic compound layer 13b was 0.5 μm. The specific gravity of polyvinyl pyrrolidone in an aqueous solution state was about 1.7. Therefore, the polyvinyl pyrrolidone spread effectively and equally to cover the second organic compound layer 13b by virtue of arranging the treatment surface of the substrate 11 upward.

(9) Lift-Off Step

Subsequently, while the substrate 11 was rotated at a rotation number of 500 rpm, the substrate 11 was scanned with a two-fluid nozzle (nozzle diameter: 5 μm) containing pure water and nitrogen gas separately at a speed of 20 mm/s from the center to the end of the substrate 11 and pure water was sprayed onto the substrate during the scanning. As a result, the eluted constituent material 23 for the intermediate layer 21 was dissolved and removed, and simultaneously, the barrier layer 24 and the second organic compound layer 13b formed on the eluted constituent material 23 for the intermediate layer 21 were also removed together with the eluted constituent material 23 for the intermediate layer 21 (FIG. 4H). In this case, the flow rate of the pure water supplied from the two-fluid nozzle was 0.5 L/min, and the flow rate of nitrogen supplied from the two-fluid nozzle was 30 L/min.

(10) Step of Forming Intermediate Layer

Next, polyvinyl pyrrolidone (PVP) as a water-soluble polymer material and water were mixed to prepare a PVP aqueous solution. Then, the prepared PVP aqueous solution was applied onto the first organic compound layer 13a and the second organic compound layer 13b to form a film by a spin coating method. The film was dried to form the intermediate layer 21. In this case, the thickness of the intermediate layer 21 was 2 μm.

(11) Step of Forming Barrier Layer

Next, a silicon nitride film was formed to provide the barrier layer 24 on the intermediate layer 21. In this case, the thickness of the barrier layer 24 was set to 2 μm.

(12) Step of Forming Resist Layer

Next, a commercially available photoresist material (“AZ1500” (trade name) manufactured by AZ Electronic Materials) was formed into a film on the barrier layer 24 by a spin coating method, and thereafter, a solvent in the photoresist material was evaporated to form the resist layer 22 (FIG. 4I). In this case, the thickness of the resist layer 22 was 1 μm.

(13) Step of Processing Second Organic Compound Layer

Next, the substrate 11 with the layers including the resist layer 22 formed thereon was set in an exposure device, and was exposed to light for 40 seconds through a photomask having openings in regions other than the region 10a in which the first organic EL element was to be provided and the region 10b in which the second organic EL element was to be provided. After the exposure to light, the resist layer was developed for 1 minute through use of a developer (obtained by diluting “312 MIF” (trade name) manufactured by AZ Electronic Materials with water to a concentration of 50%) for a resist layer. The resist layer 22 formed in the region 10c in which the third organic EL element was to be provided was removed by the developing treatment (FIG. 4J).

Next, dry etching was performed for 17 minutes through use of the remaining resist layer 22b as a mask under the following conditions. Thus, the barrier layer 24 formed in the region 10c in which the third organic EL element was to be provided was removed.

Reaction gas: CF₄

Flow rate of reaction gas: 30 sccm

Pressure: 10 Pa

Output: 150 W

Next, dry etching was performed for 5 minutes under the following conditions. Thus, the intermediate layer 21 formed in the region 10c in which the third organic EL element was to be provided was removed.

Reaction gas: O₂

Flow rate of reaction gas: 20 sccm

Pressure: 10 Pa

Output: 150 W

Next, dry etching was performed under the following conditions. Thus, the second organic compound layer 13a formed in the region 10c in which the third organic EL element was to be provided was removed (FIG. 4K).

Through the above-mentioned steps, the second organic compound layer 13b was formed selectively in the region 10b in which the second organic EL element was to be provided. Note that, when the third dry etching (dry etching performed for processing the second organic compound layer 13b) was completed, the resist layer 22b formed on the barrier layer 24 was removed in the region 10a in which the first organic EL element was to be provided and in the region 10b in which the second organic EL element was to be provided, as illustrated in FIG. 4K.

(14) Step of Forming Third Organic Compound Layer

Next, the third organic compound layer 13c formed of multiple layers including a third emission layer emitting green light was formed at least on the first electrode (12c) by continuous film formation using a vacuum deposition method.

First, a hole transport layer was formed at least on the first electrode (12c). In this case, the thickness of the hole transport layer was set to 160 nm. Then, a third emission layer containing a green light-emitting material was formed on the hole transport layer. In this case, the thickness of the third emission layer was set to 30 nm. Then, a hole block layer was formed on the third emission layer. In this case, the thickness of the hole block layer was set to 10 nm. Thus, the third organic compound layer 13c was formed (FIG. 4I).

(15) Step of Covering Third Organic Compound Layer

Next, the substrate 11 with the layers including the third organic compound layer 13c formed thereon was put in a device including a rotation mechanism and a mechanism formed of a supply pipe for a solution and a two-fluid nozzle, and then, the substrate 11 was adsorbed to a stage of the rotation mechanism with the treatment surface of the substrate 11 arranged upward. Then, while the substrate 11 was rotated at a rotation number of 500 rpm, water which was a solution for the intermediate layer 21 was supplied at a flow rate of 1 L/min for 5 seconds through use of a supply nozzle. Thus, the third organic compound layer 13c was covered with the eluted constituent material 23 for the intermediate layer 21 (FIG. 4M). In this case, the thickness of the constituent material 23 covering the third organic compound layer 13c was 0.5 μm. The specific gravity of polyvinyl pyrrolidone in an aqueous solution state was about 1.7. Therefore, the polyvinyl pyrrolidone spread effectively and equally to cover the second organic compound layer 13b by virtue of arranging the treatment surface of the substrate 11 upward.

(16) Lift-Off Step

Next, following the previous step, while the substrate 11 was rotated at a rotation number of 500 rpm, the substrate 11 was scanned with a two-fluid nozzle (nozzle diameter: 5 μm) at a speed of 20 mm/s from the center to the end of the substrate 11, and water and nitrogen gas were respectively supplied onto the substrate during the scanning. As a result, the eluted constituent material 23 for the intermediate layer 21 was dissolved and removed, and simultaneously, the barrier layer 24 and the second organic compound layer 13b remaining on the eluted constituent material 23 for the intermediate layer 21 were also removed together (FIG. 4N). In this case, the flow rate of pure water supplied from the two-fluid nozzle was 0.5 L/min, and the flow rate of nitrogen supplied from the two-fluid nozzle was 30 L/min.

(17) Step of Forming Common Layer

Next, an electron transport layer was formed on the respective organic compound layers (13a, 13b, 13c) as a layer shared by the respective organic EL elements. In this case, the thickness of the electron transport layer was set to 10 nm. Then, cesium carbonate (Cs₂CO₃) and a constituent material for an electron injection layer were co-deposited from the vapor to form an electron injection layer. In this case, the thickness of the electron injection layer was set to 20 nm. Note that, in this example, a laminate including the electron transport layer and the electron injection layer serves as the common layer 14.

(18) Step of Forming Second Electrode

Next, an Ag film was formed to provide the second electrode 15 that is semi-transparent on the common layer 14 by a sputtering method. In this case, the thickness of the second electrode 15 was set to 16 nm (FIG. 4O).

(19) Sealing Step

Finally, sealing was performed by adhering sealing glass (not shown) and the substrate 11 to each other through intermediation of an adhesive made of UV-curable resin in a nitrogen atmosphere. Thus, an organic EL device was obtained.

### Comparative Example 1

In Comparative Example 1, the steps (8) and (15) of Example 1 were performed by immersing the substrate 11 in a solution for the intermediate layer 21 for 5 seconds with the treatment surface of the substrate 11 arranged sideward (directed in a direction parallel to the gravity). As a result, the constituent material for the intermediate layer 21 was dissolved and spread into the solution without remaining on the surface of the substrate 11, with the result that the constituent material was not able to cover the second organic compound layer 13b or the third organic compound layer 3c. Except for the foregoing, an organic EL device was manufactured by the same method as that of Example 1.

(Evaluation of Organic EL Device)

Of the obtained organic EL devices, 10 devices were measured, and an average of the measurement results was defined as standard characteristics, whereby the devices were evaluated.

The obtained organic EL devices were caused to perform a white display. In the organic EL devices according to Example 1, 0.5 pixel on average did not emit light. On the other hand, in the organic EL devices according to Comparative Example 1, 30 pixels on average did not emit light. Further, in the organic EL devices according to Comparative Example 1, about 80% of the portions not emitting light corresponded to portions of damages caused on element surfaces.

Further, only an organic EL element emitting light of particular color out of red, green, and blue was caused to emit light in the organic EL devices according to Example 1 and Comparative Example 1, and at this time, voltage-current characteristics (drive voltage) and current-luminance characteristics (current efficiency) with the passage of time during continuous current-carrying were compared to each other.

When the 10 organic EL devices according to Example 1 were measured and evaluated for voltage-current characteristics, it was found that all the voltage-current characteristics were within an error of 5% of the standard characteristics of the drive voltage. In contrast, when the 10 organic EL devices according to Comparative Example 1 were similarly measured and evaluated for voltage-current characteristics, it was found that 8 devices out of the 10 devices had a drive voltage higher by about 15% to 25% compared to the standard characteristics.

When the 10 organic EL devices according to Example 1 were measured and evaluated for a change in current-luminance characteristics with the passage of time during continuous current-carrying, it was found that an average of the 10 devices at a time of elapse of 100 hours was within an error of 5% of the standard characteristics. In contrast, when the 10 organic EL devices according to Comparative Example 1 were measured and evaluated in the same way as in Example 1, it was found that an average of the 10 devices at a time of elapse of 100 hours was degraded by about 20 to 30% compared to the standard characteristics.

It is understood from the foregoing results that, according to the manufacturing method of the present invention, an organic EL device having satisfactory yield and stable characteristics can be obtained. That is, when the manufacturing method of the present invention is used, physical damages which the organic compound layer may receive during the process can be reduced, and the influence of the lift-off step can be suppressed, with the result that an organic EL device having high precision and excellent emission characteristics can be manufactured stably.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2012-147949, filed Jun. 29, 2012, which is hereby incorporated by reference herein in its entirety.

What is claimed is:

1. A method for manufacturing an organic electroluminescence device comprising multiple organic electroluminescence elements each including a first electrode, an organic compound layer, and a second electrode laminated on a substrate in the stated order, the organic compound layer being patterned in a predetermined shape,
the method comprising:
a first organic compound layer forming step of forming a first organic compound layer on the substrate on which a a plurality of the first electrodes are provided;
an intermediate layer forming step of forming an intermediate layer on the first organic compound layer;
a first organic compound layer processing step of selectively removing the intermediate layer and the first organic compound layer formed on some of the plurality of the first electrodes;
a second organic compound layer forming step of forming a second organic compound layer on the first electrode provided in a region from which the first organic compound layer has been removed;
a second organic compound layer covering step of covering the second organic compound layer with an eluted constituent material for the intermediate layer by bringing the intermediate layer into contact with a solution for dissolving the intermediate layer;
an intermediate layer removing step of removing the intermediate layer and the eluted constituent material for the intermediate layer by dissolving the intermediate layer and the eluted constituent material for the intermediate layer through use of the solution; and
a second electrode forming step of forming the second electrode on the first organic compound layer and the second organic compound layer.

2. The method according to claim 1, wherein the second organic compound layer covering step comprises holding a surface of the substrate on which the organic compound layer is formed upward and supplying a predetermined amount of the solution to the substrate.

3. The method according to claim 2, wherein the second organic compound layer covering step comprises supplying the solution to the substrate while rotating the substrate.

4. The method according to claim 1, wherein the second organic compound layer covering step comprises immersing the substrate in the solution with a surface of the substrate on which the organic compound layer is formed arranged upward.

5. The method according to claim 1, wherein the intermediate layer in a solution state has a specific gravity higher than a specific gravity of the solution.

6. The method according to claim 1, wherein the intermediate layer comprises a water-soluble material, and the solution comprises a liquid including water.

7. The method according to claim 6, wherein the intermediate layer comprises a water-soluble polymer material.

8. The method according to claim 1, further comprising a barrier layer forming step of forming a barrier layer on the intermediate layer between the intermediate layer forming step and the first organic compound layer processing step, and
further comprising a barrier layer processing step of removing the barrier layer provided in a region from which the first organic compound layer is removed before the first organic compound layer processing step.
